(19) United States
(12) Patent Application Publication
(10) Pub. No.: US 2008/0219060 A1
(43) Pub. Date: Sep. 11, 2008

(54) DEVICE AND METHOD FOR INTERNAL VOLTAGE MONITORING

(75) Inventors: Tobias Graf, Neubiberg (DE); Manfred Proell, Dorfen (DE); Stephan Schroeder, Muenchen (DE); Stefan Tuebel, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/962,925

(22) Filed: Dec. 21, 2007

(30) Foreign Application Priority Data
Dec. 22, 2006 (DE) 10 2006 061 012.1

(51) Int. Cl. G11C 7/00; G11C 29/00

(52) U.S. Cl. 365/189.07; 365/189.011; 365/201

(57) ABSTRACT

A memory device and method for internal voltage monitoring is disclosed. One embodiment includes at least one error register configured to store a particular error flag during the stress test. This error flag is generated if the supply voltage applied at the memory device during the test method in the memory device or an internally generated voltage of the memory device lies below a predetermined threshold value.

### CROSS-REFERENCE TO RELATED APPLICATIONS

This Utility patent application claims priority to German Patent Application No. DE 10 2006 061 012.1 filed on Dec. 22, 2006, which is incorporated herein by reference.

### BACKGROUND

The invention relates to integrated circuits, including a method and to a device for wafer testing, including internal voltage monitoring during wafer testing, in one embodiment during the wafer level burn-in.

For the manufacturing of semiconductor devices such as, for instance, integrated computing circuits or memory devices, thin discs of monocrystalline silicon are used, which are referred to as wafers in the technical language. In the course of the manufacturing process, the wafers are subject to a plurality of coating, exposure, etching, diffusion, and implantation processes, etc. to structure the circuits of the devices on the wafer. After the termination of the structuring processes, the devices are individualized on the wafer for further processing. To this end, the processed wafer or system wafer is, for instance, sawn apart, scratched, or broken, so as to separate the individual devices from each other.

After the structuring of the semiconductor devices (i.e. after the performing of the above-mentioned wafer processing steps), the devices that are still available on the wafer may be tested by using appropriate test devices, for instance, in wafer tests. After the sawing apart (or the scratching, and breaking) of the wafer, the devices that are then available individually are molded in a plastics mass, wherein the semiconductor devices obtain specific packages such as, for instance, TSOP or FBGA packages, etc. Subsequently, the packaged semiconductor devices may be subject to further test methods in one or a plurality of test stations.

A memory field of semiconductor memory devices with optional access (dynamic random access memory, DRAM) is, in principle, constructed of rows (word lines) and columns (bit lines). On access to a memory cell, a word line is first of all activated. Thus, the memory cells arranged in a row are each conductively connected with a bit line. At the end of the bit line, a sense amplifier is positioned which detects and amplifies the cell signal transmitted via the bit line. The amplified signal is, on the one hand, written back into the cell via the bit line and can, on the other hand, be read out to the outside. The process described here is performed simultaneously for all memory cells that are assigned to a word line. This also means that, after the activation, all bit lines are supplied with a signal.

During the manufacturing of memory components, short-circuits between line portions within a memory device may occur due to process weaknesses during the manufacturing process, e.g., due to defect density problems. Such short-circuits need not occur directly during the testing of the semiconductor memory immediately after the manufacturing process. If such short-circuits between internal lines of the memory device occur, for instance, due to thermo-electrical activation, at a later time only (e.g., at the customer of the semiconductor manufacturer), this will have an influence on the reliability assessment of the memory manufacturer.

The memory manufacturer as a rule guarantees the customer a reliability performance in the dpm range (defects per millions of memory devices). This guarantee obligates the memory manufacturer to artificially age memory devices by stress. The typical reliability-relevant mechanisms become apparent by a disproportionate failure liability in an early operating stage of the memory device. This way, a functionable, preaged memory device has a minor failure liability for the typical reliability-relevant mechanisms than a non-aged device.

For determining the functionality and reliability, the semiconductor devices are also tested in “burn-in” test systems, wherein an artificial aging of the devices is caused by the generation of extreme conditions. In such a burn-in test system, a burn-in test method is performed, in which the semiconductor device is subject to extreme conditions, such as, for instance, an increased temperature (e.g., over 80° C. up to 125° C.), or an increased operating voltage, to produce an accelerated aging of the semiconductor device.

Artificial aging may be performed with the finished and packaged semiconductor devices, which is also referred to as “component burn-in”. In one embodiment, the artificial aging may be performed still on the wafer, which is also referred to as stress on wafer level or as wafer level burn-in test. The testing on wafer level has the advantage that non-functional elements or elements destroyed by the stress may, if required, still be replaced by redundant elements on the memory chip.

The wafer level burn-in test method has the advantage that a high parallelism may be achieved by it in that, for instance, a plurality of word lines of the memory device are coupled with each other or synchronized, respectively. This entails, however, that no function tests can be performed with the memory device during the wafer level burn-in test since the word lines cannot be addressed individually due to the parallel connection. When stressing the finished memory devices in the component burn-in test, function tests with the memory device can, however, be performed, wherein the function of individual memory cells can be examined.

Another difference between the wafer level burn-in test method and the component burn-in test method consists in that, in the wafer level burn-in test, the contact pads are additionally contacted for voltage supply of the tested chips. For function examination in the component burn-in test method, data are, for instance, written in the memory cells of the memory device via the input/output channels and are subsequently read out again. If the date written in the memory cells corresponds to the date read out from the corresponding memory cells, the functional test is successful. In the case of deviating data, the memory device can be identified as defective.

A memory device is usually constructed such that a bit line contact (CB) is positioned between two GC word lines that are separated from each other by a thin insulation layer. Thus, during operation of the memory device, the thin insulation layer between the GC word line and the CB contact is subject to high potential differences, similar to the gate oxide directly below the GC word lines. An insulation break down between the CB bit line contact and the GC word lines short-circuits the GC word line with the CB bit line potential and thus constitutes a critical reliability problem.

To perform the artificial aging of memory devices with a minimum of time and costs, three “aging parameters”, namely the temperature, the chip-internal voltages, and an operation of the chip with increased parallelism vis-à-vis normal operation are substantially available for the different stress mechanisms. For the predominant number of the stress mechanisms, the internal voltage constitutes the dominating and most efficient acceleration factor. In particular for the dominating reliability problems such as, for instance, CBGC short-circuits and GC-GC-word line short-circuits. Consequently, an adjusting and maintaining of the stress voltage which are as precise as possible are required for a specific apportioning of the stress.

During the stressing on wafer level, the chip-internal voltages are impressed from outside via voltage supply channels by a needle card of a test system (tester) and further via supply voltage contact points (pads) on the chip. The inner resistance of the supply voltage channels including the needle card resistance, the transition resistance of the contact needle on the contact point of the chip, and the wiring in the chip cause voltage drops between the adjusted supply voltage and the actual stress voltage at the circuit element to be stressed. These resistances, in particular the transition resistance of the needle card and thus the voltage drop at the chip contact point, may vary from chip to chip.

Moreover, the voltage drop along the voltage path depends on the average current consumption of the chip during the stress test. The current consumption during the stress test of a chip is in turn dependent on its transistor parameters, wherein high stress voltages in the proximity of the maximum block voltage of transistors constitute the “snapback limit”. The current consumption in the memory device is further dependent on chip-individual defect density problems that might result in short-circuits in the chip.

A first problem consists in that, in wafer level stress tests with current hardware, voltage drops of the supply voltage to the chip contact point (pad) of up to approx. 700 mV, i.e. approx. 18% of the applied word line stress voltage, were measured. It was moreover found that another 10% of the stress voltage might drop between the contact point of the chip and the stress-critical circuit due to the chip-internal wiring. These voltage drops may vary from chip to chip due to the different current draw of every single chip, and from one needle contact to the other due to the different electrical contact between the contact needle of the test system and the contact point of the chip, and from one test system to the other due to the different internal resistance of the current supply channels of the test system.

A second problem consists in that many stress tests on wafer level are geared to a high parallelism for the testing or stressing of the stress mechanisms. This is, for instance, performed by the simultaneous activating of all word lines for generating a highly parallel stress between CB bit line contacts and GC word lines. The disadvantage of these test modes consists in that no functioning examination of the memory device can be performed during the stress. Thus, it would be possible that memory devices, due to faulty needle contacts, chip-internal circuit problems, or due to damages occurring during the stress test, do not experience sufficient stress conditions. Such memory devices that have not experienced sufficient stress conditions can, however, not be differentiated from correctly stressed memory chips in the wafer level burn-in method.

Another problem during the testing on wafer level consists in that the starting of operation of a memory chip with partially impressed and distinctly excessive stress voltages substantially differs from the starting of operation of a memory chip in normal operation without any impressed stress voltages. The changing of the order for switching on voltage generators of the memory chip and the generator intensity vis-à-vis a memory chip in normal operation sometimes results in that weaker voltage generators cannot achieve their target value. This may result in that the chip cannot finish the procedure of starting operation, remains in this state, and is thus no longer accessible for any control signals. Such chips would then experience no stress whatsoever, but it would not be possible for the test system to recognize them as non-tested.

In prior art, no technical solutions for the above-described problems have become known so far. The consequence are insufficiently stressed or non-stressed chips that will, with increased liability, not fulfill the reliability criteria guaranteed to the customer.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates the schematic representation of an electrical circuit for a memory device in accordance with one embodiment. The electrical circuit is completely accommodated on the memory device and is structured with the manufacturing method of the memory device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the FIGURE(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One embodiment provides for identifying chips that have, during the burn-in method on wafer level, experienced only insufficient stress or no stress, during the stress test already.

One or more embodiments provide a memory device including a number of memory cells, a number of external contact points for supplying the memory device with an electrical supply voltage, and a number of voltage generators for generating internal voltages of the memory device, wherein the memory device includes at least one error register that is configured to store a particular error flag if the supply voltage applied to one of the external contact points during a test method in the memory device or an internal voltage of the memory device lies below a predetermined threshold value.

One embodiment provides a method for the testing of memory devices including a number of memory cells, a number of external contact points for supplying the memory device with an electrical supply voltage, and a number of voltage generators for generating internal voltages of the memory device. The method includes:

contacting the memory device with a test system via the external contact points;

applying a supply voltage to the external contact points;

comparing the supply voltage applied via the external contact points in the memory device or an internal voltage of the memory device with a predetermined threshold value;

generating at least one error flag if the supply voltage applied to the external contact points during the test methods in the memory device or an internal voltage of the memory device lies below a predetermined threshold value; and

storing the generated error flag in an error register of the memory device.

In accordance with one embodiment, the memory device is equipped with at least one error register that stores a particular error flag already during the wafer level burn-in test method. In accordance with the method according to the invention, the error flag is generated if the supply voltage applied to the memory device during the test method in the memory device or an internally generated operating voltage of the memory device lies below a predetermined threshold value or below an internal reference voltage of the memory device. The memory device according to the invention and the method according to the invention thus offer the advantage that the memory devices that have not been contacted by the test system during a stress test on wafer level, or memory devices that have been destroyed by the stress can be identified during the wafer level burn-in test method already.

On principle, one embodiment is based on an internal monitoring (voltage monitoring) of the most important stress voltages of the tested memory device during the test method still. The focus lies on the wafer level burn-in method since in the above-described component burn-in method the memory devices can typically be tested by using functional tests, and thus the non-stressed chips may also be detected. Nevertheless, it is also conceivable in the component burn-in method that the stress voltages that are set by using different test modes and that are generated by the chip-internal generators do not achieve the desired intensity of the stress voltage. In the simplest case, this would be a test mode voltage value in the stress program which has deliberately been programmed too low and which could be detected by the independent internal voltage monitoring.

One embodiment provides a specific test mode that monitors the chip-internal voltages as close as possible at the circuit elements that are critical under stress conditions. Here, above all the voltages that are decisive for the stress, such as word line active voltage (VPP), word line block voltage (VNWLL), bit line center voltages (VBLEQ), and bit line high voltage (VBLH), are of importance and are therefore monitored. To this end, these voltages are compared in an appropriate distribution relationship with a threshold voltage derived from the chip-internal, constant reference voltage (bandgap reference voltage V_{BGREF})

In one embodiment, the test mode enables the programming of a minimum stress voltage threshold for each of the voltages monitored. An internal comparator circuit of the memory device or a comparator, respectively, detects the under-run of the stress voltage threshold by the monitored stress voltage and may now be stored in the error register. If required, the content of the error register may be transmitted to the output connection of the chip (chip output) still during the test method. This way, a non-recurrent under-run at the chip output can be recalled permanently and be evaluated by a downstream functional test.

Especially for the verification of the stress voltages in the wafer level test, an output of the comparator result would be possible for each of the monitored stress voltages since a plurality of data channels of the memory device to be tested are connected with the test system. Contrary to this, in the case of the component burn-in method, only one data output of the memory device is connected with the test system. In addition, in the component burn-in method, the chip output is occupied by reading cycles for the continuous checking of the functionality during the stress test. The error flag would have to be compressed on a data channel, the relevant voltages would have to be compared during the test, the failure states would have to be stored and to be readable by a command at the end of a stress sequence. One or more embodiments, however, enables the checking of the relevant stress voltages during the wafer level burn-in test method already.

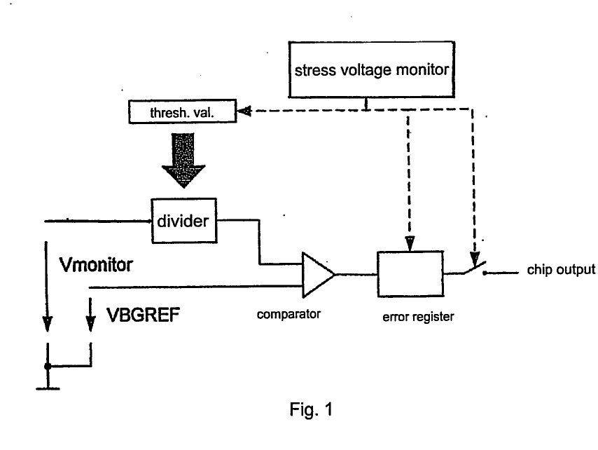

The circuit illustrated in FIG. 1 includes two voltage inputs for the electrical voltages V_{MONITOR} and V_{BGREF} which have a particular voltage value vis-à-vis a mass potential (“ground”). The voltage V_{MONITOR} is either the supply voltage applied to the external contact points, or an internal voltage of the memory device generated by the internal voltage generators, which is to be monitored by the circuit according to the invention during the wafer level burn-in test method.

The voltage input for the monitored stress voltages V_{MONITOR} is consequently either coupled with an external contact point of the memory device at which a supply voltage is applied via the test system, or is connected with an internal voltage generator of the memory device, which generates an internal operating voltage for the memory device which may also be monitored as stress voltages V_{MONITOR}.

The stress voltage V_{MONITOR} derived from an external contact point of the memory device is not the supply voltage originally provided by the test system, but the electrical voltage actually applied at an external contact point of the memory device. This may, due to contact interferences between the needle card or the contact needle of the test system and the external contact point of the memory device, be distinctly smaller than the supply voltage supplied by the test system, which would result in that the corresponding memory device or at least particular circuit blocks of the memory device are not stressed sufficiently during the wafer level burn-in method. If no contact is established between the contact needle of the test system and the external contact point of the memory device, the voltage applied at an external contact point of the memory device during the wafer level burn-in test method may even be Zero, which would result in that the corresponding memory device or at least parts of the memory device would not be stressed at all during the wafer level burn-in method.

The internal voltage generators of the memory device may, for instance, generate a word line active voltage VPP, a word line block voltage VNWLL, a bit line center voltage VBLEQ, or a bit line high voltage VBLH as internal voltage V_{MONITOR}. These internal operating voltages are particularly critical for the functionality of the memory device and can be observed with the method according to the invention under the stress conditions of a wafer level burn-in test. In the embodiment illustrated in FIG. 1, only one stress voltage V_{MONITOR} to be monitored is illustrated for a better overview.

The memory device includes a voltage generator (not illustrated) generating an internal reference voltage V_{BGREF} that is fed into the circuit via the second voltage input. The stress voltage V_{MONITOR} to be monitored is placed to the magnitude of the reference voltage V_{BGREF} (e.g., the bandgap voltage of approx. 1.1 V) by using divider via a predetermined distribution relationship. Via a stress voltage monitor circuit it is possible to program a particular threshold value into the divider so as to determine the above-mentioned distribution relationship.

The two voltage inputs for the electrical voltages V_{MONITOR} and V_{BGREF} are introduced in a comparator circuit or a comparator, respectively, which compares the two voltage values with one another. The comparator generates an error flag if the supply voltage applied to one of the external contact points during a test method in the memory device or an internal voltage of the memory device lies below the predetermined threshold value.

The comparator is coupled with an error register that stores the error flag. The error register may be configured to store a particular error flag if the supply voltage V_{MONITOR} at one or a plurality of the external contact points for voltage supply of the memory device or an internal voltage of the memory device lies below the predetermined threshold value once, intermittently, or continuously during the test method.

The error flag may also be generated and be stored in the error register if the supply voltage V_{MONITOR} in the memory device or an internal voltage V_{MONITOR} in one or a plurality of internal voltage components of the memory device lies below the predetermined threshold value once, intermittently, or continuously during the test method.

In one embodiment, the comparator compares the supply voltage V_{MONITOR} applied at an external contact point during the test method in the memory device, and/or an internal voltage V_{MONITOR} with an internal reference voltage V_{BGREF} of the memory device and initiates the generation of the error flag if the supply voltage V_{MONITOR} applied at the external contact points during the test method or an internal voltage V_{MONITOR} of the memory device lies below the internal reference voltage V_{BGREF}.

Likewise, the comparator or the comparator circuit, respectively, may generate the error flag itself if the supply voltage V_{MONITOR} applied at the external contact points during the test method in the memory device or an internal voltage V_{MONITOR} lies below the internal reference voltage V_{BGREF}, and the error flag generated is stored in the error register.

In one embodiment, the memory device according to the invention may include an OR gate that is coupled with a plurality of external contact points for voltage supply of the memory device, and/or with a plurality of internal voltage generators of the memory device. The above-mentioned divider is coupled between the external contact points and the electrical comparator circuit or the OR gate.

The OR gate compares the supply voltage V_{MONITOR} applied at the external contact points during the test method in the memory device, and/or an internally generated voltage V_{MONITOR} with the internal reference voltage V_{BGREF} of the memory device and generates the error flag if the supply voltage V_{MONITOR} applied at the external contact points during the test method, or an internal voltage V_{MONITOR} lies below the internal reference voltage V_{BGREF}. The OR gate is coupled with the error register in which the error flag generated can be stored.

As described above, the supply voltage V_{MONITOR} applied at one or a plurality of external contact points can be reduced or divided by the divider in the memory device. To this end, the divider is configured to reduce the supply voltage V_{MONITOR} applied at the external contact points during the test method in the memory device by a factor that corresponds to the quotient of internal reference voltage V_{BGREF}/supply voltage V_{MONITOR}. The supply voltage V_{MONITOR} applied by the test system at the memory device lies, for instance, in the range of 3 V, and the internal reference voltage V_{BGREF} in the range of 1.3 V. From this results a factor in the range of 1.3/3=0.433 by which the divider reduces the applied supply voltage V_{MONITOR} in the memory device.

The divider is configured to be charged via a specific test mode register and defines a predetermined threshold value that must not be under-run by the monitored stress voltages V_{MONITOR}. In this embodiment, a non-recurring under-run of this threshold voltage results in a storage of the error, for instance, in an error register which constitutes insufficient stress of the memory chip. In a later recalling of the error register, with a corresponding content of the error register, the tested memory chip may be discarded for insufficient stress.

With the activating of the monitor test mode, a resetting of the error register which stores the under-run of the monitored stress voltages V_{MONITOR} below the predetermined threshold value becomes necessary. The reading out of the signal or date stored in the error register is not possible at any time, in particular not in the case of functional stress tests in the component burn-in test method. For this reason, the test mode may additionally permit the possibility of connecting through the data content of the error register to the chip outputs already during the test method.

In accordance with one embodiment, the memory device includes a stress voltage monitor circuit by which the predetermined threshold value can be adjusted. The predetermined threshold value may be programmed into the divider by using the stress voltage monitor circuit. Furthermore, the factor by which the divider reduces the supply voltage V_{MONITOR} applied at the external contact pints during the test method in the memory device may be programmed into the divider via the stress voltage monitor circuit. The stress voltage monitor circuit may further be configured such that the data content of the error register can be programmed, read out, or reset via the stress voltage monitor circuit. These functions of the stress voltage monitor circuit are indicated by the dashed lines in FIG. 1.

Expediently, the error register is a static memory, the data content of which is maintained without voltage supply. The error register includes at least one bit that is configured to assume two states, one state of which represents the error flag. The error register includes a number of bits, so that a number of different error flags can be stored in the error register which may represent a number of different error states.

This way, the error register is configured to store a number of different error flags that represent a number of different supply voltages V_{MONITOR} in the memory device which were determined in the memory device during the test method. In one embodiment, the error register is configured to store a number of different error flags that may represent a number of different temperatures that were determined by a temperature sensor in the memory device during the test method. Furthermore, the error register may be configured to store a number of different error flags that may represent particular circuit blocks or circuit components of the memory device in which an error was detected during the test method.

One or more embodiments provide a method for testing memory devices in which the supply voltage V_{MONITOR} applied via the external contact points in the memory device and/or an internal voltage V_{MONITOR} of the memory device is/are compared with a predetermined threshold value. If the supply voltage V_{MONITOR} applied at the external contact points during the test method in the memory device or an internal voltage V_{MONITOR} of the memory device lies below the predetermined threshold value, at least one error flag is generated and stored in an error register of the memory device.

In accordance with a preferred embodiment of the method according to the invention, at least one error flag is generated if the supply voltage V_{MONITOR} applied at the external contact points during the test method in the memory device or an internal voltage V_{MONITOR} in the memory device lies below an internal reference voltage V_{BGREF} of the memory device. Subsequently, the error flag generated may again be stored in the error register.

In order to have, in the comparison of the supply voltage V_{MONITOR} in the memory device with an internal reference voltage V_{BGREF} of the memory device, voltage values of similar magnitude available, the supply voltage V_{MONITOR} applied at the external contact points during the test method is reduced or divided prior to the comparison with the predetermined threshold value or with the internal reference voltage V_{BGREF}. To this end, the supply voltage V_{MONITOR} applied at the external contact points during the test method may be reduced, prior to the comparison with the predetermined threshold value or with the internal reference voltage V_{BGREF}, by the factor corresponding to the quotient of supply voltage V_{MONITOR}/internal reference voltage V_{BGREF}.

The supply voltage V_{MONITOR} applied at the external contact points during the test method in the memory device and/or the internal voltages V_{MONITOR} of the memory device are examined in intervals or continuously.

The error register is coupled with an output channel (chip output) of the memory device via which the data content of the error register may be recalled from outside the memory device. The data content stored in the error register may, for instance, be read out by the test system during the test method in intervals or continuously.

In one embodiment, the method is suited to be performed during a wafer level burn-in test method in which an increased voltage is applied at the external contact points, which lies above the normal operating voltage of the memory device. In accordance with a further preferred embodiment of the method according to the invention, an error flag is generated from which a number of different supply voltages V_{MONITOR} can be identified, which were determined during the test method in the memory device. In one embodiment, an error flag may be generated from which a number of different internal voltages V_{MONITOR} of the memory device can be identified, which were determined during the test method in the memory device.

Furthermore, by using one embodiment of the method it is possible to generate an error flag from which a number of different temperatures can be identified which were determined by a temperature sensor in the memory device during the test method. Furthermore, an error flag may be generated from which a particular circuit block or a particular circuit component of the memory device can be identified in which an error was detected during the test method.

In accordance with one embodiment, the test system is, after the generation of an error flag, caused to detect a faulty contact to an external contact point of the memory device. The test system is, after the generation of an error flag, caused to contact the memory device via the external contact points again.

By using one embodiment of the method, memory devices that have been stressed insufficiently or that have not been stressed may be identified already during the wafer level burn-in test method by using the error flag, and the memory devices tested may be assigned to corresponding quality groups due to the data content of the error register.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device comprising:
a number of memory cells; external contact points; and voltage generators for generating internal voltages of the memory device, and
wherein the memory device comprises at least one error register that is configured to store a particular error flag if the supply voltage applied to one of the external contact points during a test method in the memory device or an internal voltage of the memory device lies below a predetermined threshold value.

2. The memory device of claim 1, comprising wherein the error register is configured to store a particular error flag if the supply voltage at a plurality of the external contact points for voltage supply of the memory device, or a plurality of internal voltages of the memory device lie under the predetermined threshold value during the test method.

3. The memory device of claim 1, comprising wherein the error register is configured to store a particular error flag if the supply voltage at one or a plurality of the external contact points for voltage supply of the memory device, or an internal voltage of the memory device lies below the predetermined threshold value once, intermittently, or continuously during the test method.

4. The memory device of claim 1, comprising wherein the error register is configured to store a particular error flag if the supply voltage or an internal voltage in one or a plurality of internal circuit components of the memory device lies below the predetermined threshold value once, intermittently, or continuously during the test method.

5. The memory device of claim 1, comprising wherein the internal voltage generators of the memory device generate a word line active voltage, a word line block voltage, a bit line center voltage (VBLEQ), or a bit line high voltage (VBLH) as internal voltage.

6. The memory device of claim 1, wherein the memory device comprises an electrical comparator circuit that compares the supply voltage applied at the external contact points during the test method in the memory device, and/or an internal voltage with an internal reference voltage of the memory device, and wherein the electrical comparator circuit initiates the generation of the error flag if the supply voltage applied at the external contact points during the test method or an internal voltage of the memory device lies below the internal reference voltage.

7. The memory device of claim 1, wherein the memory device comprises an electrical comparator circuit that compares the supply voltage applied at the external contact points during the test method in the memory device, and/or an internal voltage with an internal reference voltage of the memory device, and wherein the electrical comparator circuit generates the error flag if the supply voltage applied at the external contact points during the test method or an internal voltage lies below the internal reference voltage, and wherein the error flag generated is stored in the error register.

8. The memory device of claim 1, wherein the memory device comprises an OR gate that is coupled with the external contact points for voltage supply of the memory device, compares the supply voltage applied at the external contact points during the test method in the memory device, and/or an internal voltage with an internal reference voltage of the memory device, and generates the error flag if the supply voltage applied at the external contact points during the test method or an internal voltage lies below the internal reference voltage, and wherein the error flag generated is stored in the error register.

9. The memory device of claim 1, comprising wherein the error register is coupled with an output channel of the memory device via which the data content of the error register is configured to be recalled.

10. The memory device of claim 1, wherein the memory device comprises a divider via which the supply voltage applied to one or a plurality of external contact points is configured to be reduced or divided.

11. The memory device of claim 1, comprising wherein the divider reduces the supply voltage applied at the external contact points during the test method in the memory device by a factor corresponding to the quotient of supply voltage/internal reference voltage.

12. The memory device of claim 1, comprising wherein the divider is coupled between the external contact points and the electrical comparator circuit or the OR gate.

13. The memory device comprising:
a stress voltage monitor circuit via which the predetermined threshold value is configured to be adjusted.

14. The memory device of claim 13, comprising wherein the predetermined threshold value is configured to be programmed into the divider via the stress voltage monitor circuit.

15. The memory device of claim 13, comprising wherein the factor by which the divider reduces the supply voltage applied at the external contact points during the test method in the memory device is configured to be programmed into the divider via the stress voltage monitor circuit.

16. The memory device of claim 13, comprising wherein the data content of the error register is configured to be programmed via the stress voltage monitor circuit.

17. The memory device of claim 13, comprising wherein the data content of the error register is configured to be read out via the stress voltage monitor circuit.

18. The memory device of claim 13, comprising wherein the error register is configured to be reset via the stress voltage monitor circuit.

19. A method for testing memory devices comprising:
providing memory cells, external contact points for supplying the memory device with an electrical supply voltage, and voltage generators for generating internal voltages of the memory device, comprising:
contacting the memory device with a test system via the external contact points;
applying a supply voltage to the external contact points;
comparing the supply voltage applied via the external contact points in the memory device or an internal voltage of the memory device with a predetermined threshold value;
generating at least one error flag if the supply voltage applied at the external contact points during the test method in the memory device or an internal voltage of the memory device lies below the predetermined threshold value; and
storing the error flag generated in an error register of the memory device.

20. The method of claim 19, comprising generating at least one error flag if the supply voltage applied at the external contact points during the test method in the memory device or an internal voltage of the memory device lies below an internal reference voltage of the memory device, and storing the error flag generated in the error register.

21. The method of claim 19, comprising reducing or dividing the supply voltage applied at the external contact points during the test method, prior to the comparison with the predetermined threshold value or with the internal reference voltage.

22. The method of claim 19, comprising reducing the supply voltage applied at the external contact points during the test method, prior to the comparison with the predetermined threshold value or with the internal reference voltage by the factor that corresponds to the quotient of supply voltage/internal reference voltage.

23. The method of claim 19, comprising examining the supply voltage applied at the external contact points during the test method in the memory device, and/or the internal voltages of the memory device in intervals or continuously.

24. The method of claim 19, comprising performing the method during a wafer level burn-in test method.

25. The method of claim 19, reading out the data content stored in the error register by the test system at the end of the test method.
